(19) United States
(12) Patent Application Publication
(10) Pub. No.: US 2003/0133482 A1
(43) Pub. Date: Jul. 17, 2003

(54) Semiconductor laser device and method for reducing stimulated brillouin scattering (SBS)

(75) Inventors: Junji Yoshida, Tokyo (JP); Naoki Tsukiji, Tokyo (JP); Hiroshi Shimizu, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: The Furukawa Electric Co., Ltd., Tokyo (JP)

(21) Appl. No.: 10/308,065

(22) Filed: Dec. 3, 2002

(30) Foreign Application Priority Data
Dec. 3, 2001 (JP) 2001-369145

(51) Int. Cl. H01S 5/00

(52) U.S. Cl. 372/43

(57) ABSTRACT

A semiconductor laser device for use as a pumping source includes a light reflecting facet positioned on a first side of the semiconductor device, a light emitting facet positioned on a second side of the semiconductor device thereby forming a resonator between the light reflecting facet and the light emitting facet, and an active layer configured to radiate light in the presence of an injection current, the active layer positioned within the resonator. A wavelength selection structure is positioned within the resonator and configured to select a spectrum of the light including multiple longitudinal modes, the spectrum being output from the light emitting facet. Also included in the semiconductor laser device is a modulation device configured to superimpose a modulation signal on the injection current in order to increase a spectrum width of each of the longitudinal modes.

### CROSS REFERENCE TO RELATED APPLICATIONS

This application contains subject matter related to U.S. patent application Ser. No. 09/832,885 filed on Apr. 12, 2001; Ser. No. 09/983,175 filed on Oct. 23, 2001; Ser. No. 09/983,249 filed on Oct. 23, 2001; Ser. No. 10/014,513 filed on Dec. 14, 2001; Ser. No. 10/187,621, filed on Jul. 3, 2002; Ser. No. 10/251,835, filed on Sep. 23, 2002; and Ser. No. 10/214,177, filed on Aug. 8, 2002. The entire content of each of these applications is incorporated herein by reference.

### FIELD OF THE INVENTION

The present invention relates generally to semiconductor laser device, and in particular to a semiconductor laser device used as a pumping source for an optical amplifier.

### BACKGROUND OF THE INVENTION

With the proliferation of multimedia features on the Internet in the recent years, there has arisen a demand for larger data transmission capacity for optical communication systems. Conventional optical communication systems transmitted data on a single optical fiber at a single wavelength of 1310 nm or 1550 nm, which have reduced light absorption properties for optical fibers. However, in order to increase the data transmission capacity of such single fiber systems, it was necessary to increase the number of optical fibers laid on a transmission route, which resulted in an undesirable increase in costs.

In view of this, there has recently been developed wavelength division multiplexing (WDM) optical communications systems such as the dense wavelength division multiplexing (DWDM) system wherein a plurality of optical signals of different wavelengths can be transmitted simultaneously through a single optical fiber. These systems generally use an Erbium Doped Fiber Amplifier (EDFA) to amplify the data light signals as required for long transmission distances. WDM systems using EDFA initially operated in the 1550 nm band which is the operating band of the Erbium Doped Fiber Amplifier and the band at which gain flattening can be easily achieved. While use of WDM communication systems using the EDFA has recently expanded to the small gain coefficient band of 1580 nm, there has nevertheless been an increasing interest in an optical amplifier that operates outside the EDFA band because the low loss band of an optical fiber is wider than a band that can be amplified by the EDFA; a Raman amplifier is one such optical amplifier.

In a Raman amplifier system, a strong pumping light beam is pumped into an optical transmission line carrying an optical data signal. As is known to one of ordinary skill in the art, a Raman scattering effect causes a gain for optical signals having a frequency approximately 13 THz smaller than the frequency of the pumping beam (The pumping wavelength is approximately 100 nm shorter than the signal wavelength which is typically in the vicinity of 1500 nm.) Where the data signal on the optical transmission line has this longer wavelength, the data signal is amplified. Thus, unlike an EDFA where a gain wavelength band is determined by the energy level of an Erbium ion, a Raman amplifier has a gain wavelength band that is determined by a wavelength of the pumping beam and, therefore, can amplify an arbitrary wavelength band by selecting a pumping light wavelength. Consequently, light signals within the entire low loss band of an optical fiber can be amplified with the WDM communication system using the Raman amplifier and the number of channels of signal light beams can be increased as compared with the communication system using the EDFA.

For the EDFA and Raman amplifiers, it is desirable to have a high output laser device as a pumping source. This is particularly important for the Raman amplifier, which amplifies signals over a wide wavelength band, but has relatively small gain. However, merely increasing the output power of a single longitudinal mode pumping source leads to undesirable stimulated Brillouin scattering and increased noises at high peak power values. Therefore, the Raman amplifier requires a pumping source laser beam having a plurality of Oscillating longitudinal modes. As seen in FIGS. 30A and 30B, stimulated Brillouin scattering has a threshold value Pth at which the stimulated Brillouin scattering is generated. For a pumping source having a single longitudinal mode as in the oscillation wavelength spectrum of FIG. 30A, the high output requirement of a Raman amplifier, for example 300 mW, causes the peak output power of the single mode to be higher than Pₜₕ thereby generating undesirable stimulated Brillouin scattering. On the other hand, a pumping source having multiple longitudinal modes distributes the output power over a plurality of modes each having relatively a low peak value. Therefore, as seen in FIG. 30B, a multiple longitudinal mode pumping source having the required output power can be acquired within the threshold value Pₜₕ thereby eliminating the stimulated Brillouin scattering problem and providing a larger Raman gain.

The Furukawa Electric Co., Ltd. has recently developed an integrated diffraction grating device that provides a high output multiple mode laser beam suitable for use as a pumping source in a Raman amplification system. An integrated diffraction grating device, as opposed to a conventional fiber Bragg grating device, includes the diffraction grating formed within the semiconductor laser device itself. Examples of multiple mode oscillation of the integrated diffraction grating devices are disclosed in U.S. patent application Ser. Nos. 09/832,885 filed Apr. 12, 2001, 09/983,175 filed on Oct. 23, 2001, and 09/983,249 filed on Oct. 23, 2001, assigned to The Furukawa Electric Co., Ltd. and the entire contents of these applications are incorporated herein by reference.

While the Ser. Nos. 09/832,885, 09/983,175, and 09/983,249 patent applications provide the multiple mode operation needed to reduce stimulated Brillouin scattering thereby allowing a higher output power pumping source, the persistent need to provide higher pumping power for amplification creates a need to further suppress stimulated Brillouin scattering.

### SUMMARY OF THE INVENTION

Accordingly, one object of the present invention is to provide a laser device and method suitable for use as a forward pumping light source in a Raman amplification system, but which reduces the above described problems.

Another object of the present invention is to provide a laser device having improved SBS characteristics.

According to a first aspect of the present invention, a semiconductor device and method for providing a light source suitable for use as a pumping light source in a Raman amplification system are provided. The device upon which the method is based includes a light reflecting facet positioned on a first side of the semiconductor device, a light emitting facet positioned on a second side of the semiconductor device thereby forming a resonator between the light reflecting facet and the light emitting facet, and an active layer configured to radiate light in the presence of an injection current, the active layer positioned within the resonator. A wavelength selection structure is positioned within the resonator and configured to select a spectrum of the light including multiple longitudinal modes, the spectrum being output from the light emitting facet. Also included in the semiconductor laser device is a modulation device configured to superimpose a modulation signal on the injection current in order to increase a spectrum width of each of the longitudinal modes.

The modulation device may be configured to superimpose a sinusoidal modulation signal, or a modulation signal having a modulation depth in the range of about 1%-10% of the injection current, on the injection current. Alternatively, the modulation device may be configured to superimpose on the injection current a modulation signal having a modulation depth in the range of about 1%-10% of a light output of the laser device. Still alternatively, the modulation device may be configured to superimpose on the injection current a modulation signal having a modulation frequency of greater than 1 KHz, or in the range of 1 KHz to 1 MHz.

The semiconductor laser device may further include an attenuation device configured to attenuate an optical output power of the laser diode for reducing SBS. In this configuration, the modulation device may be configured to superimpose on the injection current a modulation signal having a modulation depth in the range of about 0.1%-10% of the injection current, or a modulation signal having a modulation depth in the range of about 0.1%-10% of the light output of the laser device. Alternatively, the modulation device may be configured to superimpose on the injection current a modulation signal having a modulation frequency of greater than 1 KHz, or approximately in the range of 1 KHz to 1 MHz.

The diffraction grating may be positioned adjacent to either the light emitting or light reflecting facets. Where the grating is adjacent to the light emitting facet, a length of the partial diffraction grating and a length of the resonator are set to meet the inequality Lg×(1300/L)≦300, and a length and a coupling coefficient of the partial diffraction grating are set to meet the inequality κ·Lg≦0.3. Where the diffraction grating is positioned adjacent to the light reflecting facet, a length of the partial diffraction grating and a length of the resonator are set to meet the inequality Lg≦½L, and a length and a coupling coefficient of the partial diffraction grating is set to meet the inequality: κ·Lg≧1.

The semiconductor laser device may also include a current suppression region configured to suppress current injected into the wavelength selection structure. Moreover, the wavelength selection structure may include a diffraction grating positioned along a portion of the active layer in a distributed feedback (DFB) configuration, or a wavepath layer positioned along a portion of the resonator length where no active layer exists in a distributed Bragg reflector (DBR) configuration and a diffraction grating positioned within the wavepath layer. In either configuration, the diffraction grating may be chirped grating.

Where the DBR configuration is used, the semiconductor laser device may include a first electrode configured to provide the injection current and positioned along the active layer, and a second electrode positioned along the wavepath layer and configured to supply a tuning current to the wavepath layer. In this configuration, the first electrode is electrically insulated from the second electrodes and the injection current and tuning current are independently adjustable, and injection current is unmodulated and the modulation device is configured to superimpose a modulation signal on the tuning current. A phase adjustment layer positioned within the resonator along a portion of the resonator length interposed between the active layer and the wavepath layer, in which case a third electrode positioned along the phase adjustment layer and electrically insulated from the first and second electrodes.

According to another aspect of the invention, a semiconductor laser module, an optical amplifier, a Raman amplifier, or a wavelength division multiplexing system may be provided with a semiconductor laser device for a pumping source including a light reflecting facet positioned on a first side of the semiconductor device, a light emitting facet positioned on a second side of the semiconductor device thereby forming a resonator between the light reflecting facet and the light emitting facet, and an active layer configured to radiate light in the presence of an injection current, the active layer positioned within the resonator. A wavelength selection structure is positioned within the resonator and configured to select a spectrum of the light including multiple longitudinal modes, the spectrum being output from the light emitting facet. Also included in the semiconductor laser device is a modulation device configured to superimpose a modulation signal on the injection current in order to increase a spectrum width of each of the longitudinal modes.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a partial cutaway view illustrating a semiconductor laser device according to a first embodiment of the present invention;

FIG. 2 is a vertical sectional view in the longitudinal direction of the semiconductor laser shown in FIG. 1;

FIG. 3 is a cross sectional view along the line A-A of the semiconductor laser device shown in FIG. 2;

FIG. 4 is an oscillation wavelength spectrum of the light output of a diffraction grating semiconductor laser device without a modulated injection of drive current;

FIG. 5 shows the oscillation wavelength spectrum of the light output of a diffraction grating semiconductor laser device having a modulated drive current in accordance with the present invention;

FIG. 6 is a graph showing the affect of a widened spectrum width on the power threshold value Pth for stimulated Brillouin scattering in a fiber;

FIG. 7 is a graph showing the spectrum width of each mode as a function of modulation signal amplitude;

FIG. 8 is a graph showing wavelength changes in response to current changes in the semiconductor laser device;

FIG. 9 is a graph showing the current-light output characteristic (I-L curve) of a semiconductor laser device according to the present invention;

FIG. 10 is a graph showing the changes in time of the light output of a laser device driven by a drive current having a 1% modulation amplitude;

FIG. 11 is a graph showing the relationship of the relative intensity noise to the modulation frequency;

FIG. 12 is a graph showing the SBS ratio as a function of modulation frequency for a laser device having a cavity length of ratio μm and a modulation signal depth of 0% to 10%;

FIG. 13 is a graph showing the SBS ratio as a function of modulation frequency for a laser device having a cavity length of 1500 μm and a modulation signal depth of 0%-10%;

FIG. 14 is a graph showing SBS return loss as a function of longitudinal mode number for varying modulation depths;

FIG. 15 is a vertical sectional view in the longitudinal direction of a semiconductor laser device in accordance with a second embodiment of the present invention;

FIG. 16 is a vertical sectional view in the longitudinal direction of a semiconductor laser device in accordance with a third embodiment of the present invention;

FIG. 17 is a vertical sectional view in the longitudinal direction of a variation of the semiconductor laser device shown in FIG. 16;

FIG. 18 is a graph showing the SBS reflection as a function of attenuation amount for six sample integrated diffraction grating devices;

FIG. 19 is a graph illustrating the principle of a composite oscillation wavelength spectrum produced by a grating having a first period Λ₁ and a second period Λ₂ smaller than Λ₁;

FIG. 20 illustrates a periodic fluctuation of the grating period of a diffraction grating used in a semiconductor laser device in accordance with the present invention;

FIGS. 21A through 21C illustrate examples for realizing the periodic fluctuation of the diffraction grating in accordance with the present invention;

FIG. 22 is a vertical sectional view illustrating the configuration of a semiconductor laser module having a semiconductor laser device according to the present invention;

FIG. 23 is a block diagram illustrating a configuration of a Raman amplifier used in a WDM communication system in accordance with the present invention;

FIGS. 24 and 25 show a block diagram illustrating a configuration of a Raman amplifier, used in a WDM communication system in a forward and bidirectional pumping method respectively, in accordance with the present invention;

FIG. 26 is a block diagram illustrating a configuration of a Raman amplifier in which polarization dependent gain is suppressed by depolarizing a pumping light beam output from a single semiconductor laser device using polarization maintaining fibers as a depolarizer, in accordance with an embodiment of the present invention;

FIGS. 27 and 28 show a block diagram illustrating a configuration of a Raman amplifier used in a WDM communication system in a forward and bidirectional pumping method respectively, in accordance with the present invention;

FIG. 29 is a block diagram illustrating a general configuration of the WDM communication system to which the Raman amplifier shown in any of FIGS. 23-28 is applied; and

FIGS. 30A and 30B are graphs showing the SBS threshold value Pth for single mode and multiple mode laser devices respectively.

### DESCRIPTION OF THE PREFERRED EMBODIMENTS

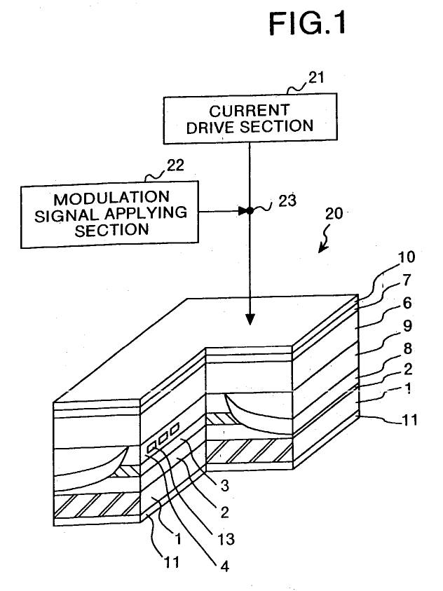

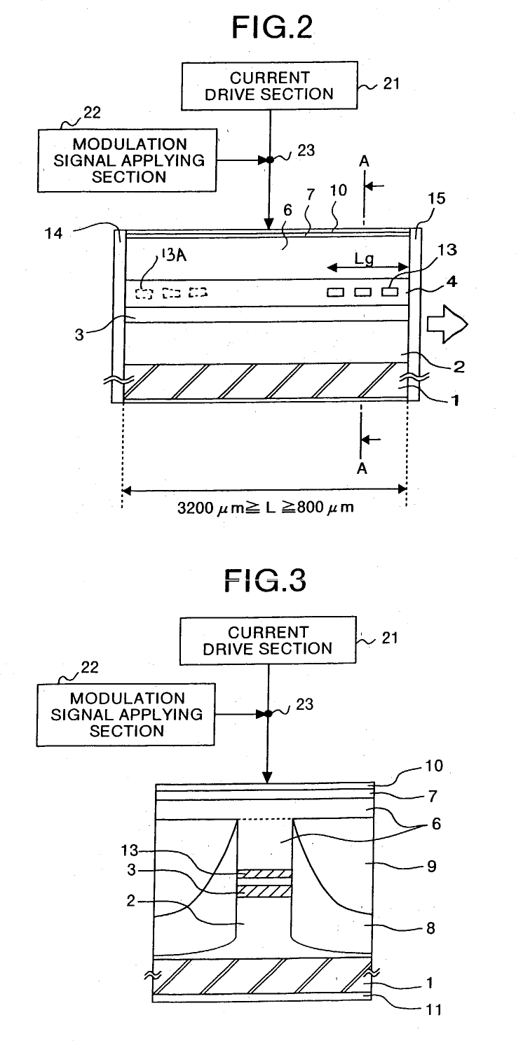

Referring now to the drawings wherein like elements are represented by the same reference designation throughout, and more particularly to FIG. 1 thereof, there is shown a semiconductor laser device for providing a light source suitable for use as a pumping light source in a Raman amplification system, in accordance with the present invention. FIG. 1 is a partial cutaway view of the semiconductor device, FIG. 2 is a vertical sectional view in the longitudinal direction of the semiconductor laser device, and FIG. 3 is a cross sectional view of the semiconductor laser device, taken along the line A-A in FIG. 2.

The semiconductor laser device 20 of FIGS. 1 through 3 includes an n-InP substrate 1 having an n-InP buffer layer 2, an active layer 3, a p-InP spacer layer 4, a p-InP cladding layer 6, and a P-InGaAsP contact layer 7 sequentially stacked on a crystal face (100) of the substrate 1. Buffer layer 2 serves both as a buffer layer by the n-InP material and an under cladding layer, while the active layer 3 is a graded index separate confinement multiple quantum well (GRIN-SCH-MQW) structure having a compressive strain. A diffraction grating 13 of a p-InGaAsP material is periodically formed within the p-InP spacer layer 4 along a portion of the length of the laser resonator. Finally, a p-side electrode 10 is formed on the upper surface of p-InGaAsP cap layer 7, and an n-side electrode 11 is formed on the back surface of n-InP substrate 1.

As seen in FIG. 2, reflective film 14 having high reflectivity of, for example, 80% or more, and preferably 98% or more is formed on a light reflecting end surface that is one end surface in the longitudinal direction of the semiconductor laser device 20. Antireflection coating 15 having a low reflectivity of 10% or less, preferably less than 5%, less than 1%, or less than 0.5%, and most preferably less than 0.1% is formed on a light irradiating end surface opposing the light reflecting end surface of semiconductor laser device 20. The reflective film 14 and the diffraction grating including antireflection coating 15 form an optical resonator within the active region 3 of the semiconductor laser device 20. A light beam generated inside the GRIN-SCH-MQW active layer 3 of the light resonator is reflected by the reflective film 14 and irradiated as an output laser beam via the antireflection coating 15, while the oscillation wavelength being selected by the diffraction grating 13. Moreover, as best seen in FIG. 3, the p-InP spacer layer 4 having the diffraction grating 13, the GRIN-SCH-MQW active layer 3, and the upper part of the n-InP buffer layer 2 are processed in a mesa stripe shape. The sides of the mesa stripe are buried by a p-InP current blocking layer 8 and an n-InP current blocking layer 9 forming a buried-hetero (BH) structure. The BH structure allows the injection current to be effectively concentrated into the active layer and to control the single transverse oscillation mode.

As seen in FIGS. 1-3, the semiconductor laser device 20 also includes a current drive section 21 that applies a bias or drive current to the p side electrode 10, and a modulation signal applying section 22 that applies a modulation frequency signal that modulates the drive current. The modulation frequency signal may be any cyclic signal such as a sine wave or delta wave signal. However, because cyclic signals other than a pure sine wave contain a plurality of sine wave with different frequency components, it is desirable that a sine wave signal is used for the modulation frequency signal. Modulation frequency signals output from the modulation signal applying section 22 are superimposed on the drive current at a connection point 23 to provide a modulated drive current, and the modulated drive current is applied to the p side electrode 10.

The laser device 20 of FIGS. 1-3 is constructed so as to provide multiple longitudinal mode oscillation of the laser device. Thus, as seen in FIG. 2, the resonator length L is preferably from 800-3200 microns as described in U.S. patent application Ser. No. 09/832,885 which is incorporated herein by reference. In the embodiment of FIGS. 1 through 3, the diffraction grating 13 has a length Lg of approximately 15 μm, a grating layer thickness of 20 nm, a grating pitch of 220 nm, and selects a laser beam having a central wavelength of 1480 nm to be emitted by the semiconductor laser device 20. Where the partial grating 13 is positioned on the light emitting side of the laser device as shown in FIGS. 1-3, it is preferable that the diffraction grating length Lg and the resonator length L are set to satisfy the relationship Lg×(1300 μm/L)≦300 μm. Moreover, the diffraction grating 13 is preferably constructed such that a value obtained by multiplying a coupling coefficient κ of the diffraction grating by a diffraction grating length Lg is set to 0.3 or less. By setting these parameters, multimode operation of the laser device having a diffraction grating on a light emitting side can be achieved. Examples of devices having a diffraction grating provided in the vicinity of the radiation side reflecting film may be found in U.S. patent application Ser. No. 09/983,249, which is incorporated herein by reference.

A partial grating 13A (shown in phantom in FIG. 2) may be positioned on the light reflecting side of the laser device and preferable has a grating length Lg and the resonator length L are set to satisfy the relationship Lg≦½L. Moreover, the diffraction grating 13A is preferably constructed such that a value obtained by multiplying a coupling coefficient κ of the diffraction grating by a diffraction grating length Lg is set to 1 or more, and selectively returns light to the radiation side by the effective reflectivity of the diffraction grating being 98% or higher. By setting these parameters, multimode operation of the laser device having a diffraction grating on a light reflecting side can be achieved. Examples of devices having a diffraction grating provided in the vicinity of the radiation side reflecting film may be found in U.S. patent application Ser. No. 09/983,175, which is incorporated herein by reference. Of course, the laser device may have a diffraction grating on either or both the light reflecting side and the light emitting side of the device, or a single diffraction grating positioned substantially along the entire length of the active layer.

The present inventors have discovered that a modulated drive current provided by the modulation signal applying section 22 and current drive section 21 provides improved SBS characteristics for the laser device 20. Specifically, when the value of the drive current applied to the semiconductor laser device changes, the effective refractive index n of the light emitting region of the laser light of the GRIN-SCH-MQW active layer 3 and the like also changes. When the refractive index n changes, the resonator length Lop of the laser device also changes optically. That is, if the physical resonator length is taken as L, then the optical resonator length Lop is represented by

Lop=n·L

Thus, the optical resonator length changes to track the changes in the effective refractive index. This change in the optical resonator length Lop causes the mode interval between each longitudinal mode of the laser device to change.

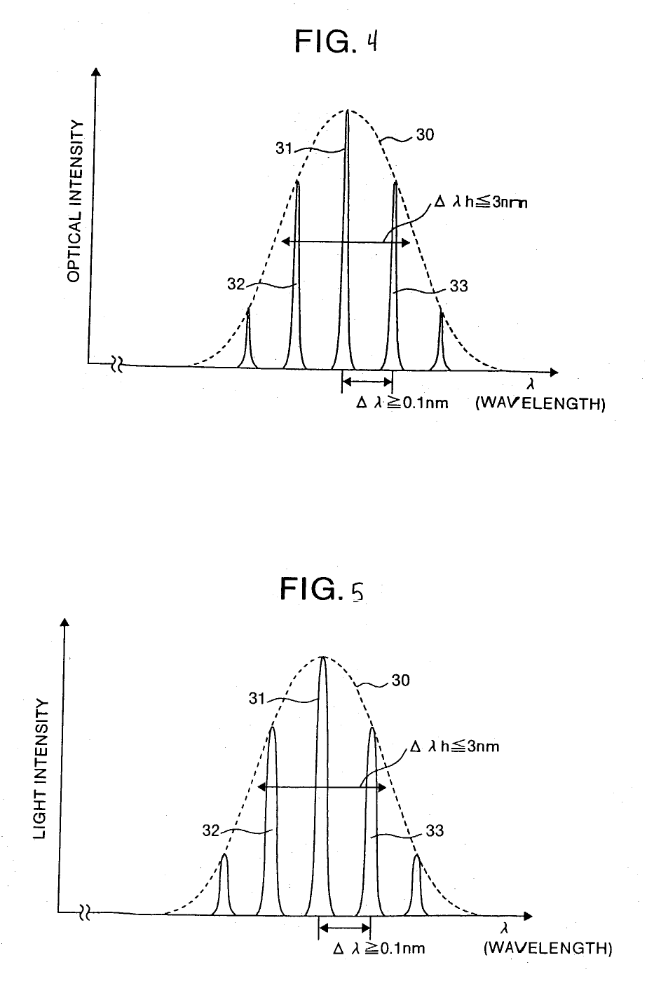

FIG. 4 shows the oscillation wavelength spectrum of the light output of a diffraction grating semiconductor laser device without a modulated injection or drive current. As seen in this figure, the oscillation wavelength spectrum 30 provides multiple longitudinal modes including center frequency mode 31, and modes 32 and 33, separated by a wavelength interval Δλ. As also seen in FIG. 4, the wavelength interval Δλ is preferably in the range of 0.1 nm to 3 nm. FIG. 5 shows the oscillation wavelength spectrum of the light output of a diffraction grating semiconductor laser device having a modulated drive current in accordance with the present invention. As seen in this figure, each of the multiple longitudinal modes has a wider spectrum than the longitudinal modes of FIG. 4 due to the modulation of the drive current.

FIG. 6 shows the effect of the widened spectrum width on the power threshold value Pth for stimulated Brillouin scattering in a fiber. As shown in FIG. 6, if the spectrum width of each mode increases, the stimulated Brillouin scattering threshold value Pth also increases. That is, the wider the spectrum of each longitudinal mode of the laser device, the higher the output power of the device can be before SBS will occur in a fiber coupled to the device. Thus, the present inventors have discovered that modulation of the driving current provides a stable high power output having improved SBS characteristics for a given fiber.

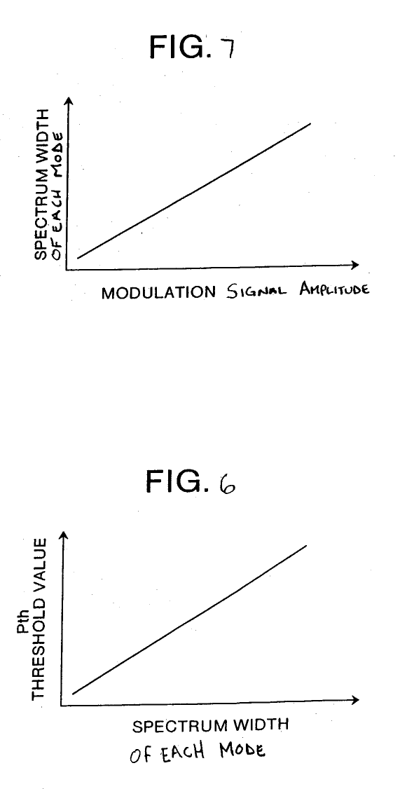

The present inventors have also discovered that the amount of spectrum widening of each mode of the multimode laser device depends on the amplitude of the modulation signal provided by the modulation signal applying section 22. FIG. 7 is a graph roughly showing the relation between spectrum width of each mode and modulation signal amplitude. As seen in the figure, the spectrum width of each mode generally increases (and therefore Pth generally increases) as the modulation signal amplitude increases. However, the present inventors have also discovered that uncontrolled modulation of the drive current may lead to undesirable operational characteristics of the laser device.

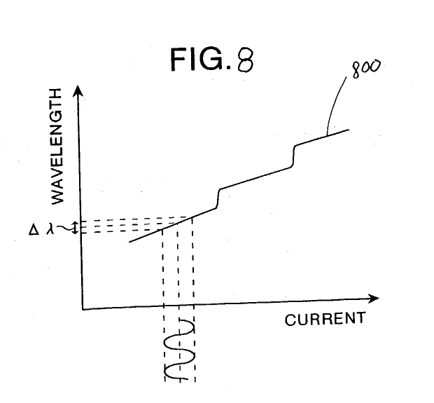

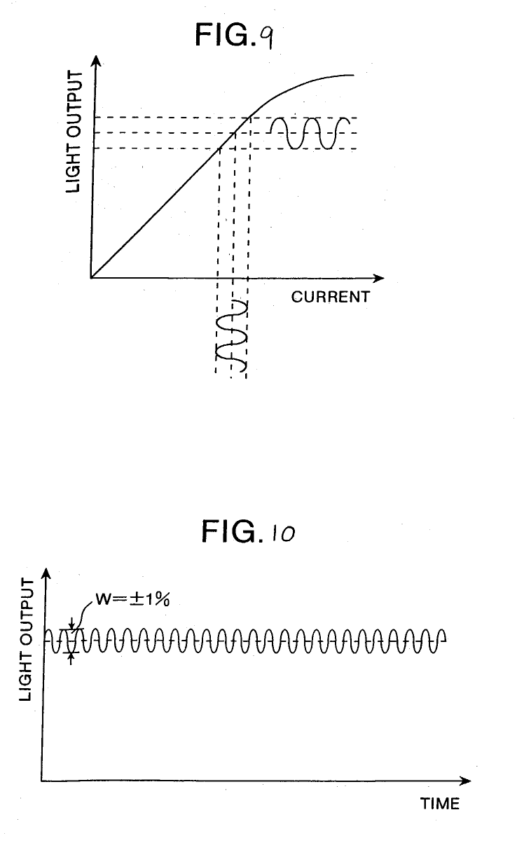

First, the modulation of the drive current may cause mode hopping of the semiconductor laser device. As discussed above, the modulation of the drive current causes a variation in the wavelength oscillation of the longitudinal modes. FIG. 8 is a graph showing wavelength changes in response to current changes in the semiconductor laser device. As is shown in FIG. 8, the wavelength increases somewhat monotonically as the drive current increases, except for particular regions of the current axis where abrupt wavelength changes occur due to the laser device “mode hopping” to an adjacent longitudinal oscillation mode. Accordingly, it is necessary for the amplitude of the modulation signal and the magnitude of the drive current to be selected such that the current change is generated in a region where the wavelength change is minute. That is, the present inventors have discovered that the modulation depth of the signal must be limited in order to maintain laser operation in a monotonic region of the current wavelength characteristic.

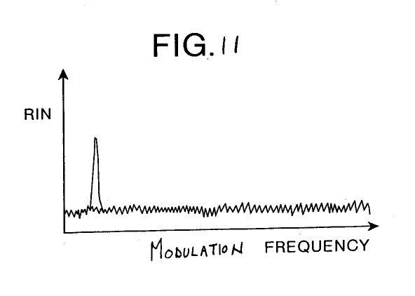

In addition, the modulation of the drive current causes the light output of the laser device to vary. FIG. 9 is a graph showing the current-light output characteristic (I-L curve) of the semiconductor laser device according to the present invention. As seen in this figure, modulation of the drive current causes a corresponding modulation in the light output of the laser device. Where the modulation frequency signals are sine wave signals having an amplitude value of 1% of the value of the bias current, the amplitude of the light output when driven only by the bias current is changed sinusoidally by 1%. FIG. 10 is a view which shows the changes in time of the light output of a laser device driven by a drive current having a 1% modulation amplitude. However, the present inventors have recognized that larger current variations cause large light output variations which may be undesirable for applications of the laser device.

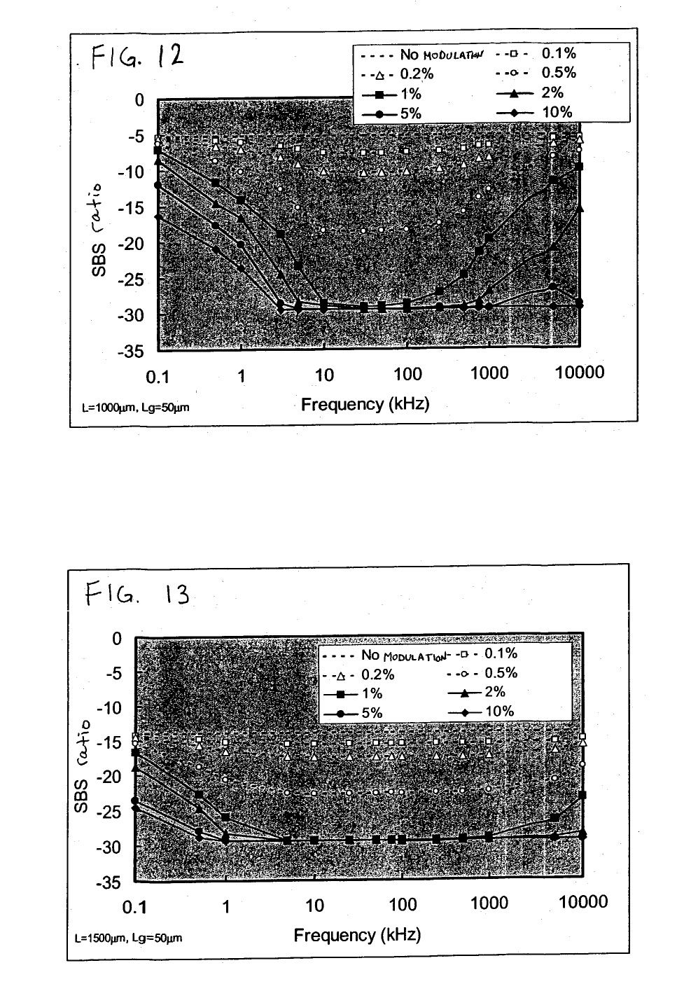

Finally, the present inventors have recognized that the modulation signal becomes a noise component of the light output of the laser device. FIG. 11 is a graph showing the relationship of the relative intensity noise to the modulation frequency. Low frequency modulation frequency signal components give a large RIN value. Thus, the frequency region of the modulation signal must be carefully selected to avoid excessive RIN.

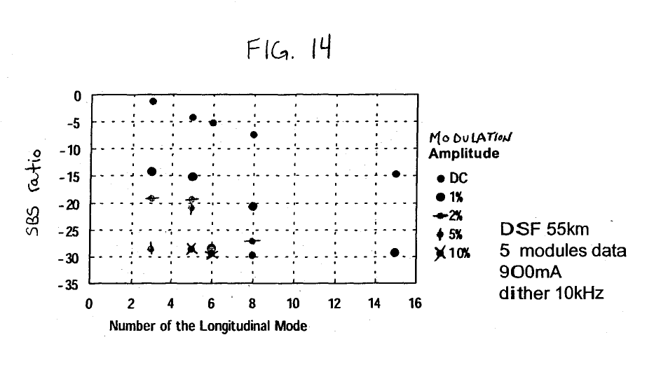

Thus, the present inventors have discovered that, while modulating the injection current reduces SBS, the modulation depth and frequency may be controlled to improve the operating characteristics of the laser device. Therefore, the present inventors conducted experiments in which the modulation depth and frequency of a drive current signal were varied for laser devices having the general structure described in FIGS. 1-3. FIG. 12 is a graph showing the SBS ratio as a function of modulation frequency for a laser device having a cavity length of 1000 μm and a modulation signal depth of 0% (i.e. no modulation) to 10%. Here, the SBS ratio is defined as a ratio of the backscattered light output power induced by the SBS to the input power of the pump source. Similarly, FIG. 13 is a graph showing the SBS ratio as a function of modulation frequency for a laser device having a cavity length of 1500 μm and a modulation signal depth of 0%-10%. The modulation depth or amplitude, given as a percentage, is the amount by which the modulation increases or decreases the drive current value without modulation. For example, a modulation depth of 10% means that the modulation signal increases or decreases the drive current by 10% (i.e., ±10%) with a total variation of 20%. As seen in FIGS. 12 and 13, the grating length of the devices tested was 50 μm. Moreover, in both figures, curves resulting from actual test data are shown in solid lines, while curves extrapolated from the test data are shown in dashed lines. The modulation signal used for FIGS. 12 and 13 was a sine wave.

As seen in FIGS. 12 and 13, a modulation frequency signal in the range of several kHz to several hundred MHz and having an amplitude value of approximately 1 to 10% the value of the bias current provides reduced SBS ratio for both the 1000 μm and 1500 μm devices. In this regard, it is noted that the amplitude value is not limited to approximately 1% to 10% the value of the bias current and may be defined as being value of approximately 1% to 10% the value of the light output.

While improvements in SBS ratio occurred at approximately the same modulation depth and frequency ranges in FIGS. 12 and 13, a comparison of these FIGS. 12 and 13 reveals that the SBS return loss is larger in the case of shorter cavity length (1000 μm) device. This is supposed to be due to the longitudinal mode number increasing with an increase in the cavity length. FIG. 14 is a graph showing SBS return loss as a function of longitudinal mode number for varying modulation depths. As seen in the figure, five samples having different mode numbers were driven with a bias current of 900 mA and a modulation frequency of 10 kHz, while changing the modulation frequency of each sample. Each sample had a cavity length of 1500 μm and grating length of 50 μm, and the longitudinal mode number was estimated at 10 dB down from peak power. As seen in FIG. 14, as the mode number is increased, the SBS can be suppressed by a smaller modulation depth. For examples, LDs having 5 or less longitudinal modes require modulation depth of 10% or more in order to suppress SBS. LDs having 6 or more longitudinal modes require a modulation index of 5% or less in order to suppress SBS.

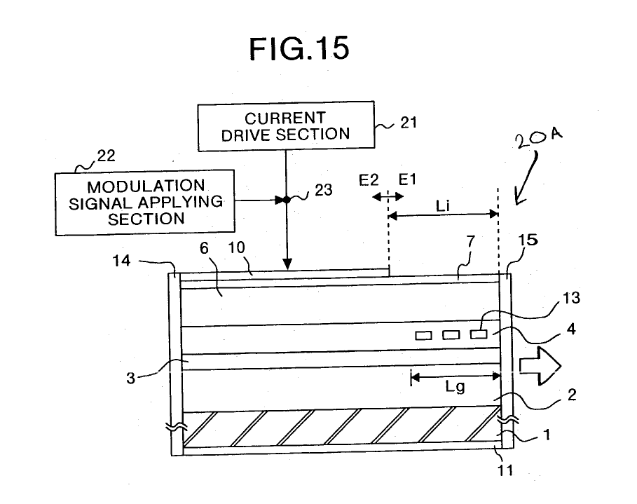

FIG. 15 is a vertical sectional view in the longitudinal direction of a semiconductor laser device 20A in accordance with a second embodiment of the present invention. As seen in FIG. 15, the second embodiment of the invention is similar to the first embodiment except for a current suppression region E1 corresponding to the diffraction grating 13. Therefore, elements common to the first and second embodiments are not described with respect to FIG. 15. As seen in FIG. 15, the non-current injection area E1 of the second embodiment is formed by a partial p-side electrode 10. Specifically, the semiconductor laser device of FIG. 15 includes a p-InGaAsP contact layer 7 formed upon the p-InP cladding layer 6. The p-side electrode 10 is then formed on the upper surface of this InGaAsP contact layer 7, except in the area of the diffraction grating 13. The diffraction grating 13 of the second embodiment has an approximate length of Lg=50 μm and the area Li where the electrode 10 omitted is approximately 60 μm. Therefore, non-current injection area E1 is formed along the diffraction grating 13, thereby suppressing current in the region of the diffraction grating. Suppression of the injection current in the area of the grating reduces fluctuations in the wavelength selection characteristics of the grating 13. Alternative methods of suppressing current in the region of the diffraction grating are disclosed in U.S. patent application Ser. No. 10/014,513, the entire contents of which is incorporated herein by reference.

As in the first embodiment, a plurality of oscillation longitudinal modes are formed using diffraction grating 13 in the laser device 20A of the second embodiment. By superimposing modulation frequency signals on a bias current, the light output energy of the laser light is dispersed, and when the laser light is used as the excitation light source in a Raman amplifier, the generation of stimulated Brillouin scattering is suppressed and laser light of the desired wavelength is output stably and with a high efficiency of optical output.

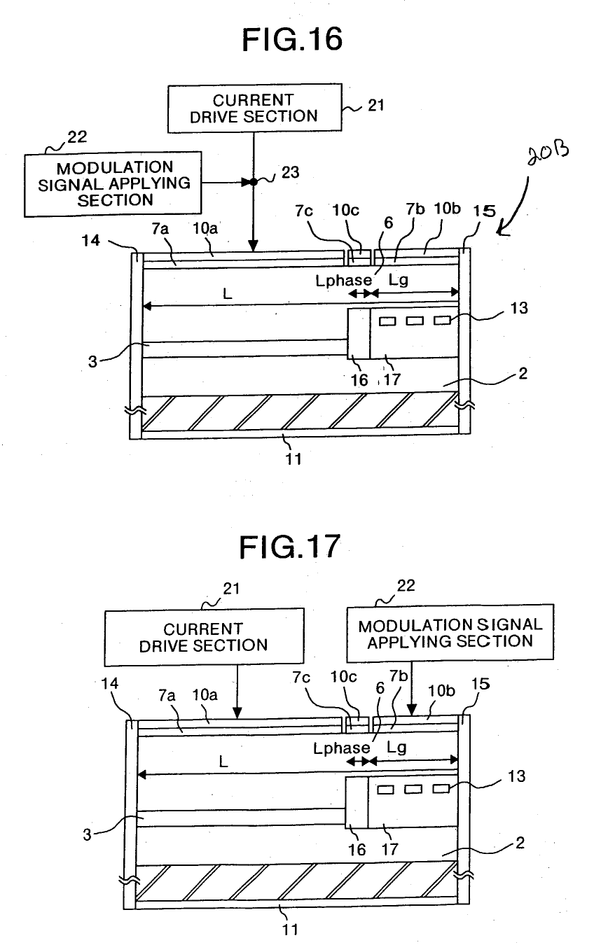

FIG. 16 is a vertical sectional view in the longitudinal direction of a semiconductor laser device 20B in accordance with a third embodiment of the present invention. The semiconductor laser device of FIG. 16 includes an active region for generating light by radiation recombination, and a wavelength selection region for determining a wavelength of the light output from the laser device. The active region is situated on the left side of the device illustrated in FIG. 16 and includes an n-InP substrate 1 having an n-InP buffer layer 2, an active layer 3, a p-InP cladding layer 6, and p-InGaAsP contact layer 7 sequentially stacked on a face (100) of the substrate 1. Buffer layer 2 serves both as a buffer layer by the n-InP material and an under cladding layer, while the active layer 3 is a graded index separate confinement multiple quantum well (GRIN-SCH-MQW) having a compression strain.

The wavelength selection region is situated on the right side of the device illustrated in FIG. 16 and includes the n-InP substrate 1 having the n-InP buffer layer 2, a GaInAsP light guiding wavepath layer 17, and p-InP cladding layer 6, sequentially stacked on a face (100) of the substrate 1. The laser device also includes a phase matching portion interposed between the active region and the wave selection region. Specifically, the phase matching region includes the n-InP substrate 1 having the n-InP buffer layer 2, a light guiding wavepath layer 4, and p-InP cladding layer 6 sequentially stacked on a face (100) of the substrate 1. As shown in FIG. 16, a p-InGaAsP contact layer 7b with electrode 10b, and p-InGaAsP contact layer 7C with electrode 10C are provided in the wavelength selection and phase selection regions respectively where these regions will be used for tuning. A diffraction grating 13 of a p-InGaAsP material is periodically formed within the wavepath layer 4.

As seen in FIG. 16, reflective film 14 having high reflectivity of, for example, 80% or more, and preferably 98% or more is formed on a light reflecting end surface that is one end surface in the longitudinal direction of the semiconductor laser device 20. Antireflection coating 15 having low reflectivity of, for example, less than 2% and preferably less than 0.1%, is formed on a light irradiating end surface opposing the light reflecting end surface of semiconductor laser device 20. The reflective film 14 and the diffraction grating region including the antireflection coating 15 form a light resonator within the active region 3 of the semiconductor laser device 20.

Thus, the embodiment of FIG. 16 provides the grating 13 in a distributed Bragg reflector (DBR) configuration where the grating is outside the gain region. This provides high production yields because the materials used for the grating structure can be selected without regard to gain considerations. Moreover, by separating the active region from the wavelength selection region as shown in FIG. 16, a more stable and efficient output can be achieved, and the wavelength selection region and phase region can be independently controlled by independent current sources. Variations of the DBR configuration are disclosed in U.S. patent application Ser. No. 10/187,621, filed on Jul. 3, 2002 and Attorney docket No. 220145US filed on Aug. 8, 2002, the entire contents of these applications being incorporated herein by reference.

As in the first embodiment, a plurality of oscillation longitudinal modes are formed using diffraction gratings 13 in the laser device 20B of the third embodiment. By superimposing modulation frequency signals on a bias current, the light output energy of the laser light is dispersed, and when the laser light is used as the excitation light source in a Raman amplifier, the generation of stimulated Brillouin scattering is suppressed and laser light of the desired oscillation wavelength is output stably and with a high efficiency of optical output.

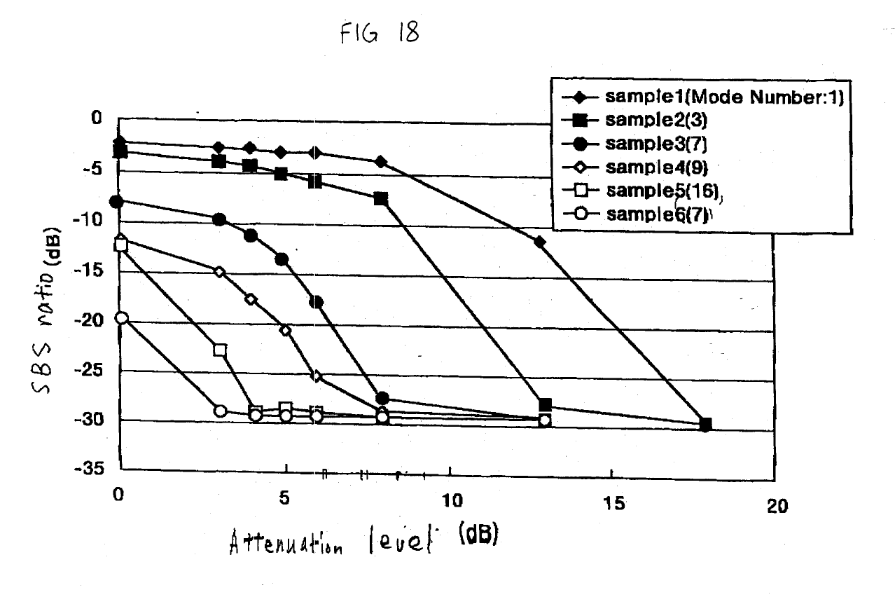

FIG. 17 is a vertical sectional view in the longitudinal direction of a variation of the semiconductor laser device shown in FIG. 16. In FIG. 17, a semiconductor laser device otherwise having the same structure as that shown in FIG. 16 is provided with a p side electrode 10b and a p-InGaAsP contact electrode layer 7b in the portion corresponding to the top portion of the diffraction grating 13. In this case, it is also possible for a p side electrode 10c and a p-InGaAsP contact electrode layer 7c to be formed in one area of the portion corresponding to the top portion of the optical waveguide path layer 16. However, they need to be insulated from the p side electrode 10a and the p side electrode 10b formed on the top portion of the GRIN-SCH-MQW active layer 3.

In FIG. 17, the bias current supplied from the current drive section 21 is applied to the p side electrode 10a without modulation, and a modulation frequency signal supplied from the modulation frequency signal applying section 22 is applied to the p side electrode 10b. As a result, a change is generated in the refractive index of the optical waveguide path layer 17 and the optical resonator length changes. This causes the spectrum width of the oscillation longitudinal modes to be made wider thereby suppressing SBS.

As in the first embodiment, a plurality of oscillation longitudinal modes are formed using diffraction gratings 13 in this variant example of the third embodiment. By applying modulation frequency signals on a bias current, the light output energy of the laser light is dispersed, and when the laser light is used as the excitation light source in a Raman amplifier, the generation of stimulated Brillouin scattering is suppressed and laser light of the desired oscillation wavelength is output stably and with a high efficiency of optical output.

While the embodiments of FIGS. 15, 16 and 17 are shown with respect to a wavelength selection region positioned on the light emitting side, One of ordinary skill in the art should understand that a wavelength selection region positioned on either or both the light emitting and light reflecting sides of the laser device may be used. Moreover, while embodiments 1 to 3. have described modulation of the drive current as the sole method of reducing SBS, further improvement can be obtained by combining attenuation methods with the drive current modulation. FIG. 18 is a graph showing the SBS ratio as a function of attenuation amount for six sample integrated diffraction grating devices having different longitudinal mode numbers. As seen in this figure, the mode numbers of samples 1, 2, 3, 4, 5, and 6 are 1, 3, 7, 9, 16, and 7 respectively. As also seen in this figure, as the attenuation level is increased, the SBS level is reduced. Moreover, when the attenuation level is 7 and 8 dB, the SBS ratio of samples 3-6 become very low. U.S. patent application Ser. No. 10/251,835 filed Sep. 23, 2002, which is incorporated herein by reference, discloses various configurations for providing attenuation. Thus, where attenuation is used to initially reduce SBS, a smaller modulation index can be used to suppress SBS in accordance with the present invention.

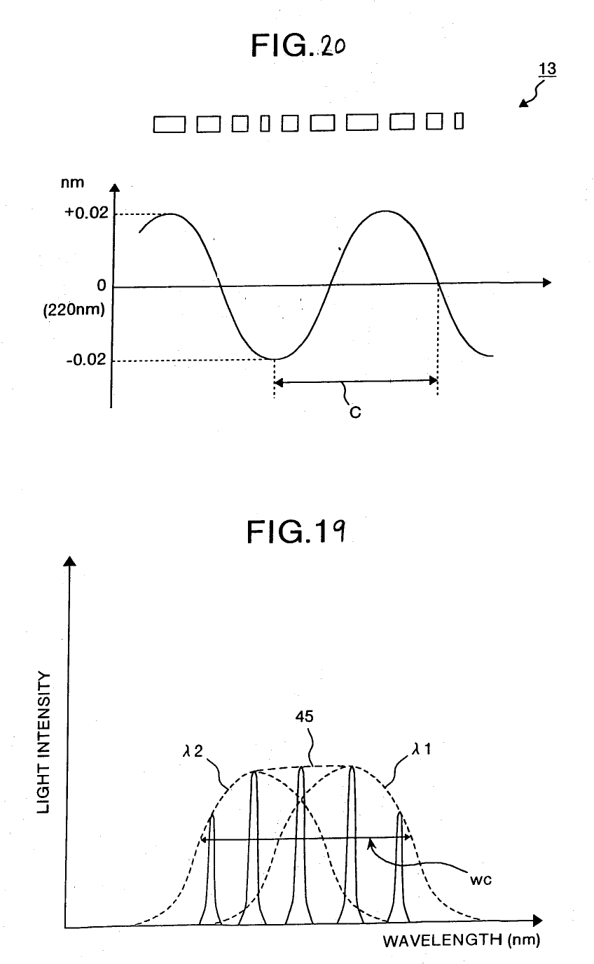

Finally, in each of the embodiments described above, the periodically spaced material of the diffraction grating 13 is equally spaced and has a constant pitch. However, it is to be understood that the grating material may have different spacings and pitches in order to achieve the desired multiple oscillation modes from the laser device. FIG. 19 is a graph illustrating the principle of a composite oscillation wavelength spectrum produced by a grating having a first period Λ₁ and a second period Λ₂ smaller than Λ₁. As seen in FIG. 19, an oscillation wavelength spectrum corresponding to Λ₁ is produced at a longer wavelength than the oscillation wavelength spectrum corresponding to Λ₂ since the period Λ₁ is larger than Λ₂. Where these individual oscillation wavelength spectrums are made to overlap such that a short wavelength half power point of the spectrum of Λ₁ is at a shorter wavelength than a long wavelength half power point of the spectrum of Λ₂, a composite oscillation wavelength spectrum 45 is formed as shown in FIG. 19. This composite spectrum 45 defines a composite spectrum width wc to thereby effectively widen the predetermined spectral width of wavelength oscillation spectrum to include a larger number of oscillation longitudinal modes.

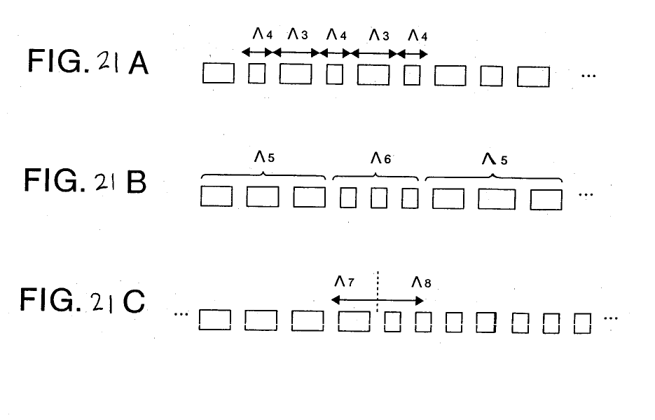

FIG. 20 illustrates a periodic fluctuation of the grating period of a diffraction grating used in a semiconductor laser device in accordance with the present invention. As shown in FIG. 20, the diffraction grating 13 has a structure in which the average period is 220 nm and the periodic fluctuation (deviation) of ±0.02 nm is repeated in the period C. Although the chirped grating is one in which the grating period is changed in the fixed period C in the above-mentioned embodiment, configuration of the present invention is not limited to this, and the grating period may be randomly changed between a period Λ₁ (220 nm+0.02 nm) and a period Λ₂ (220 nm−0.02 nm). Moreover, as shown in FIG. 21A, the diffraction grating may be made to repeat the period Λ₃ and the period Λ₄ alternately. In addition, as shown in FIG. 21B, the diffraction grating may be made to alternatively repeat the period Λ₅ and the period Λ₆ for a plurality of times respectively and may be given fluctuation. And as shown in FIG. 21C, the diffraction grating may be made to have a plurality of successive periods Λ₇ followed by plurality of successive periods Λ₈.

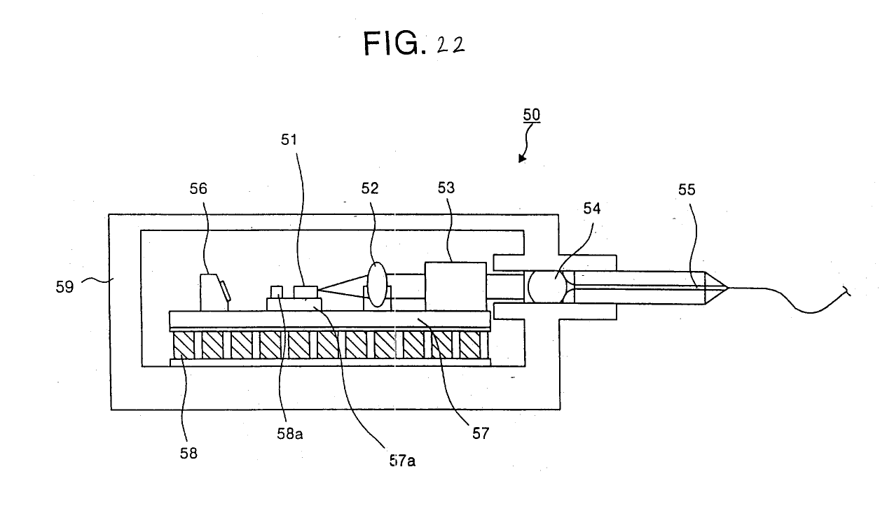

FIG. 22 is a vertical sectional view illustrating the configuration of a semiconductor laser module having a semiconductor laser device according to the present invention. The semiconductor laser module 50 includes a semiconductor laser device 51, a first lens 52, an internal isolator 53, a second lens 54 and an optical fiber 55. Semiconductor laser device 51 is an integrated grating device configured in accordance with any of the above-described semiconductor laser devices and a laser beam irradiated from the semiconductor laser device 51 is guided to optical fiber 55 via first lens 52, internal isolator 53, and second lens 54. The second lens 54 is provided on the optical axis of the laser beam and is optically coupled with the optical fiber 50.

The semiconductor laser device 51 is preferably provided in a junction down configuration in which the p-side electrode is joined to the heat sink 57a, which is mounted on the base 57. A back facet monitor photo diode 56 is also disposed on a base 57 which functions as a heat sink and is attached to a temperature control device 58 mounted on the metal package 59 of the laser module 50. The back facet monitor photo diode 56 acts as a current monitor to detect a light leakage from the reflection coating side of the semiconductor laser device 51.

The temperature control device 58 is a Peltier module. Although current (not shown) is given to the Peltier module 58 to perform cooling and heating by its polarity, the Peltier module 58 functions mainly as a cooler in order to prevent an oscillation wavelength shift by the increase of temperature of the semiconductor laser device 51. That is, if a laser beam has a longer wavelength compared with a desired wavelength, the Peltier element 58 cools the semiconductor laser device 51 and controls it at a low temperature, and if a laser beam has a shorter wavelength compared with a desired wavelength, the Peltier element 58 heats the semiconductor laser device 51 and controls it at a high temperature. By performing such a temperature control, the wavelength stability of the semiconductor laser device can improved. Alternatively, a thermistor 58a can be used to control the characteristics of the laser device. If the temperature of the laser device measured by a thermistor 58a located in the vicinity of the laser device 51 is higher, the Peltier module 58 cools the semiconductor laser device 51, and if the temperature is lower, the Peltier module 58 heats the semiconductor laser device 51. By performing such a temperature control, the wavelength and the output power intensity of the semiconductor laser device are stabilized.

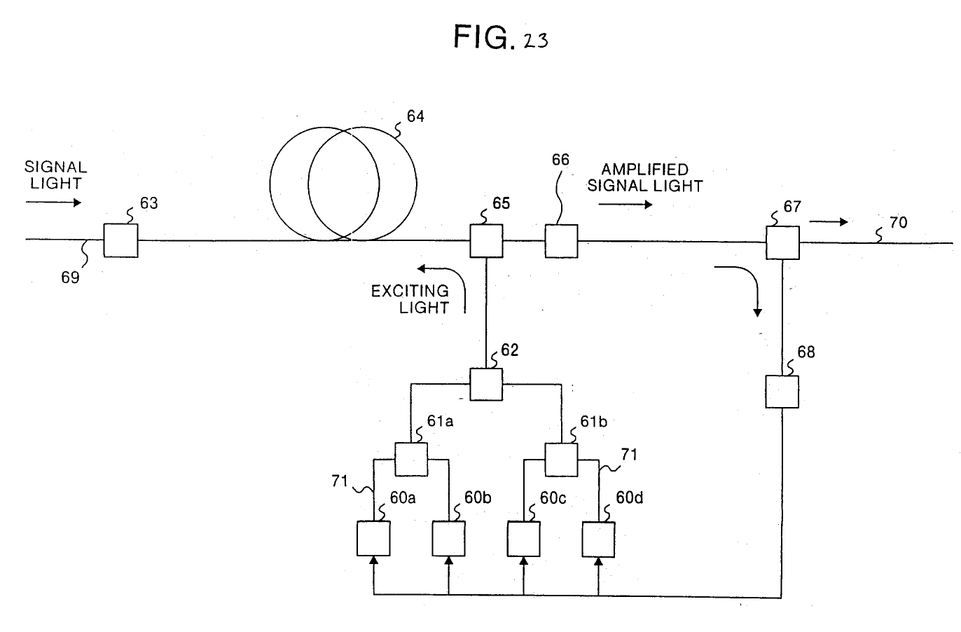

In FIG. 23, semiconductor laser modules 60a through 60d are of the type described in the embodiment of FIG. 22. The laser modules 60a and 60b output laser beams having the same wavelength via polarization maintaining fiber 71 to polarization beam combiner. Similarly, laser beams outputted by each of the semiconductor laser modules 60c and 60d have the same wavelength, and they are polarization-multiplexed by the polarization beam combiner 61b. Each of the laser modules 60a through 60d outputs a laser beam having a plurality of oscillation longitudinal modes in accordance with the present invention to a respective polarization beam combiners 61a and 61b via a polarization maintaining fiber 71.

Polarization beam combiners 61a and 61b output polarization-multiplexed laser beams having different wavelengths to a WDM coupler 62. The WDM coupler 62 multiplexes the laser beams outputted from the polarization beam combiners 61 a and 61b, and outputs the multiplexed light beams as a pumping light beam to amplifying fiber 64 via WDM coupler 65. Signal light beams to be amplified are input to amplifying fiber 64 from signal light inputting fiber 69 via isolator 63. The amplified signal light beams are Raman-amplified by being multiplexed with the pumping light beams and input to a monitor light branching coupler 67 via the WDM coupler 65 and the polarization-independent isolator 66. The monitor light branching coupler 67 outputs a portion of the amplified signal light beams to a control circuit 68, and the remaining amplified signal light outputs as an output laser beam to signal light outputting fiber 70.

The control circuit 68 controls a light-emitting state, for example, an optical intensity, of each of the semiconductor laser module 60a through 60d based on the portion of the amplified signal light beams input to the control circuit 68. This optical intensity of the Raman amplifier output is used along with the monitor current photodiode 56 of the laser module in FIG. 22 to control the output of the semiconductor lasers of each module. Thus, control circuit 68 performs feedback control of a gain band of the Raman amplification such that the gain band will be flat over wavelength.

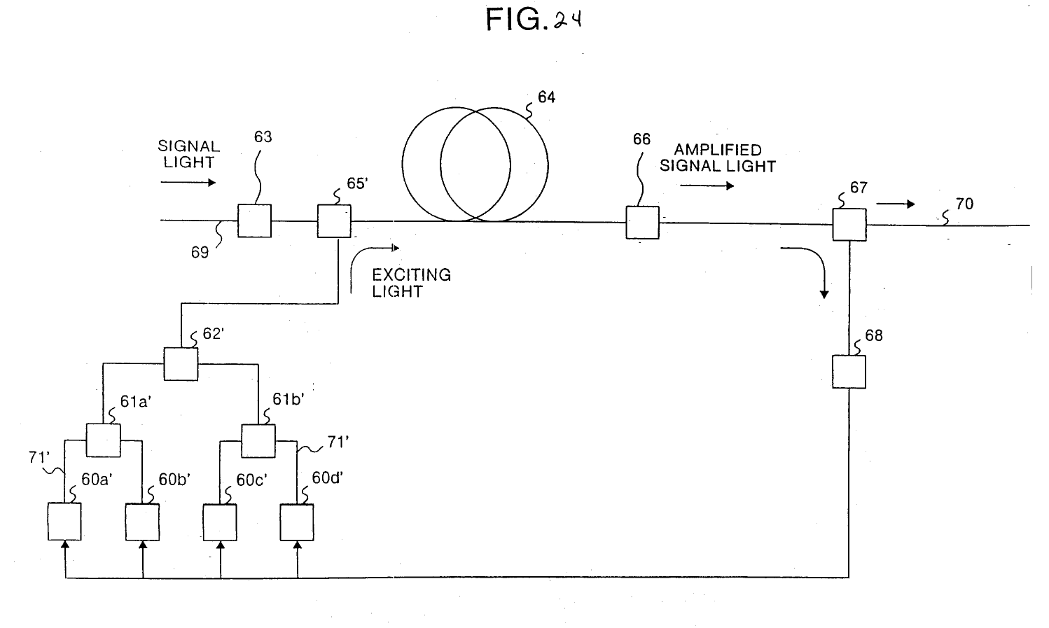

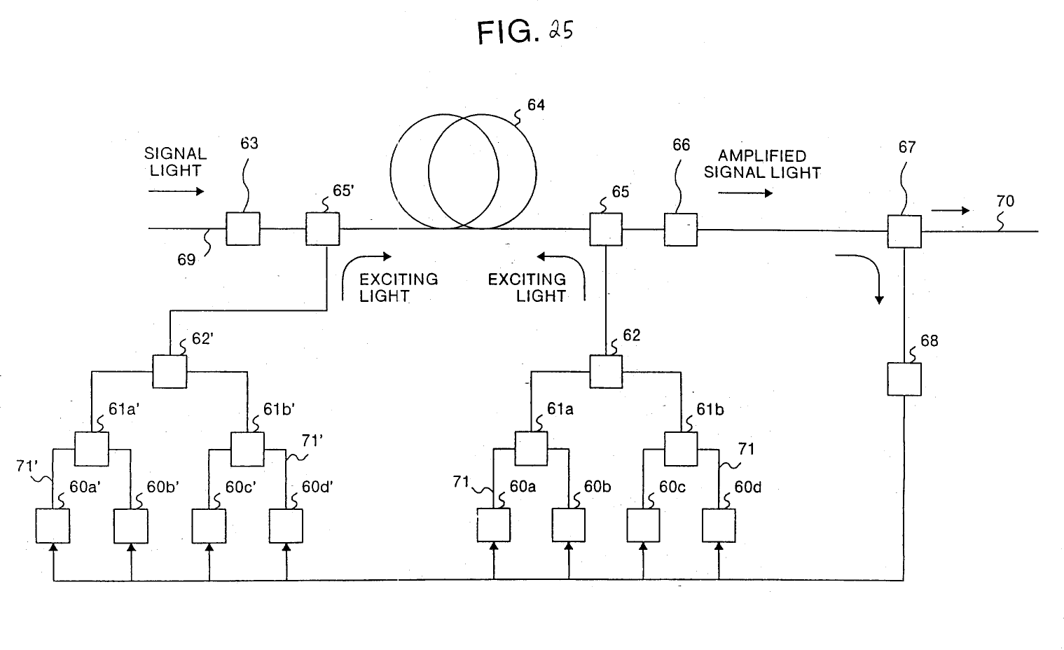

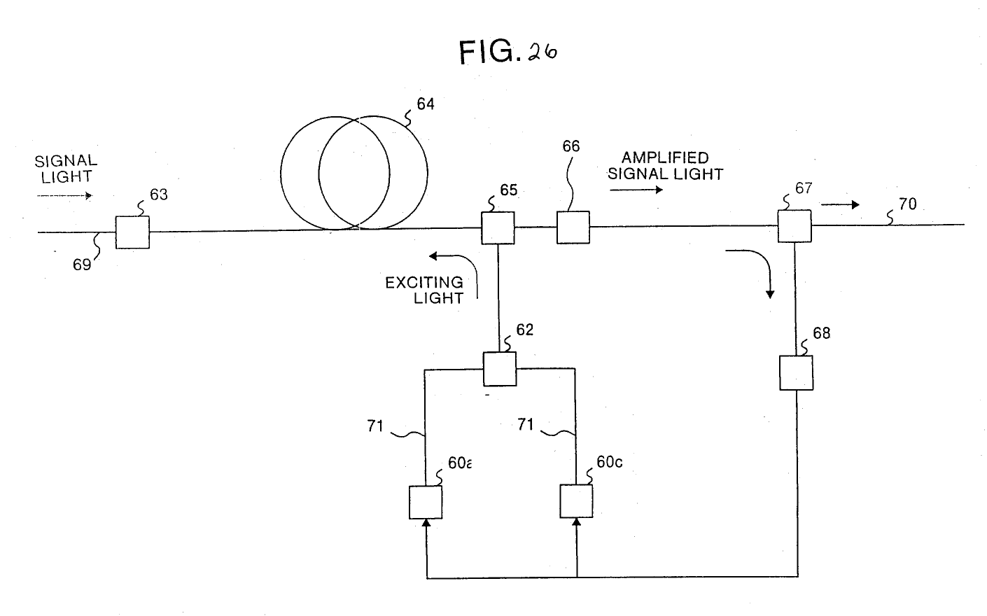

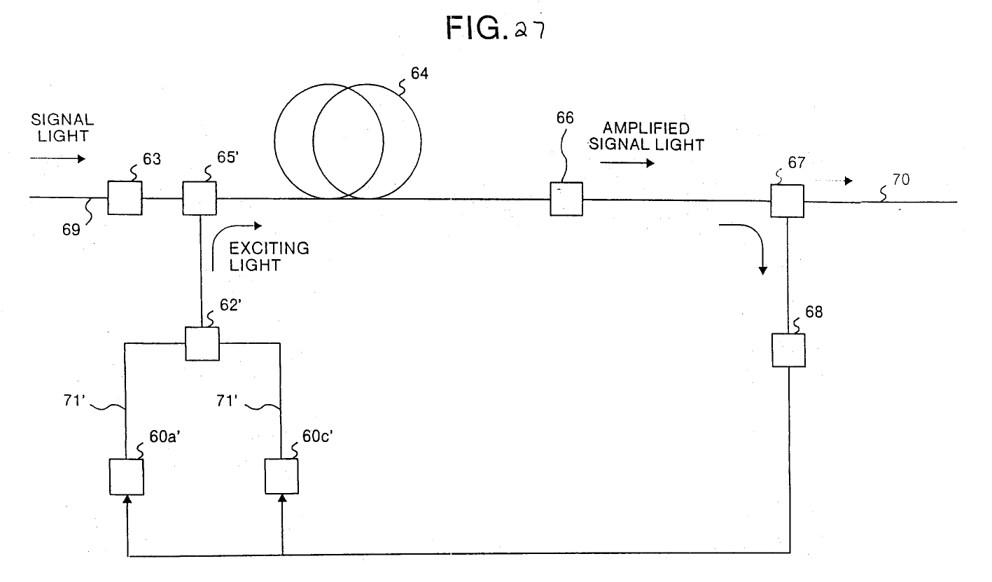

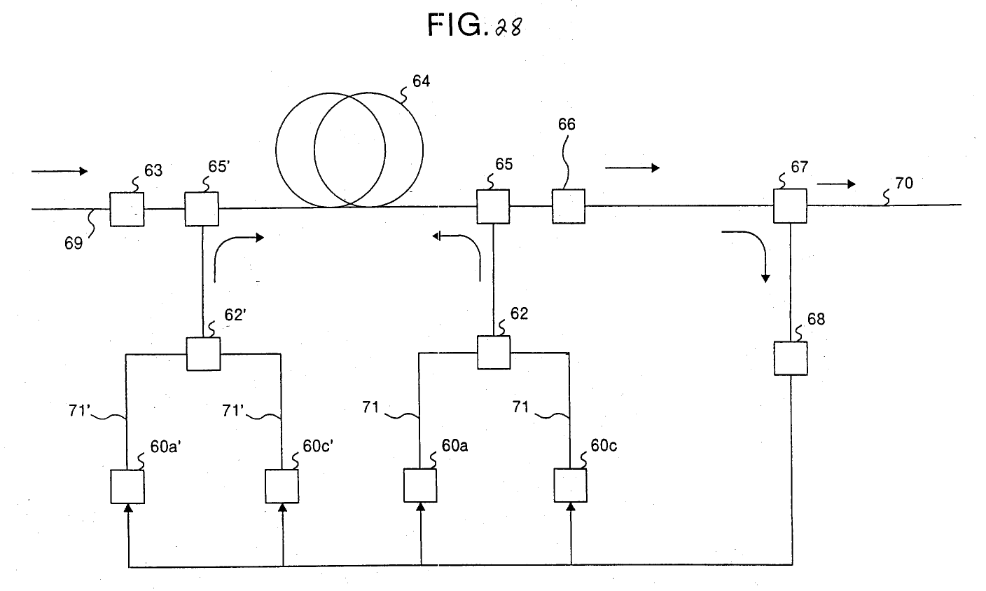

Although the Raman amplifier illustrated in FIG. 23 is the backward pumping method, it is to be understood that the semiconductor laser device, module and Raman amplifier of the present invention may be used with a forward pumping method as shown in FIG. 24, or the bi-directional pumping method as shown in FIG. 25. Moreover, the Raman amplifier can be constructed by wavelength-multiplexing of a plurality of pumping light sources which are not polarization-multiplexed. That is, the semiconductor laser module of the present invention can be used in a Raman amplifier where the polarization-multiplexing of pumping light is not performed. FIG. 26 is a block diagram illustrating a configuration of a Raman amplifier in which polarization dependent gain is canceled by depolarizing a pumping light beam output from a single semiconductor laser device using polarization maintaining fibers as a depolarizer, in accordance with an embodiment of the present invention. As seen in this figure, laser modules 60A and 60C are directly connected to WDM coupler 62 via a polarization maintaining fiber 71. In this configuration, the angle of the polarization axis of the polarization maintaining fiber against the emitted light from semiconductor laser device is approximately 45 degrees. Finally, it is to be understood that the semiconductor laser device, module and Raman amplifier of the present invention shown in FIG. 26 may be used with a forward pumping method as shown in FIG. 27, or the bi-directional pumping method as shown in FIG. 28.

The Raman amplifier illustrated in FIGS. 23-28 can be applied to the WDM communication system as described above. FIG. 23 is a block diagram illustrating a general configuration of the WDM communication system to which the Raman amplifier shown in any of FIGS. 23-28 is applied.

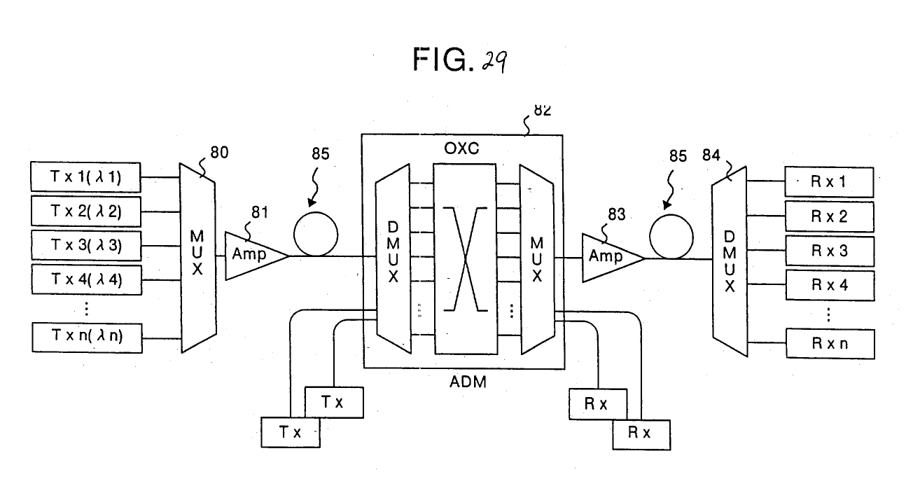

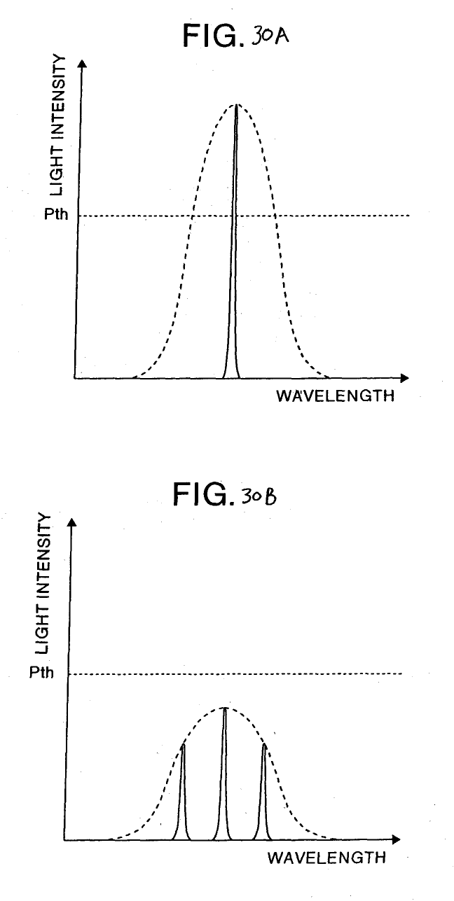

In FIG. 29, optical signals of wavelengths λ₁ through λₙ are forwarded from a plurality of transmitter Tx₁ through Txₙ to multiplexing coupler 80 where they are wavelength-multiplexed and output to optical fiber 85 line for transmission to a remote communications unit. On a transmission route of the optical fiber 85, a plurality of Raman amplifiers 81 and 83 corresponding to the Raman amplifier illustrated in FIGS. 23-28 are disposed amplifying an attenuated optical signal. A signal transmitted on the optical fiber 85 is divided by an optical demultiplexer 84 into optical signals of a plurality of wavelengths λ₁ through λₙ, which are received by a plurality of receivers Rx₁ through Rxₙ. Further, an ADM (Add/Drop Multiplexer) may be inserted on the optical fiber 85 for inserting and removing an optical signal of an arbitrary wavelength.

Obviously, numerous modifications and variations of the present invention are possible in light of the above teachings. It is therefore to be understood that within the scope of the appended claims, the invention may be practiced otherwise than as specifically described herein. For example, the present invention has been described as a pumping light source for the Raman amplification, it is evident that the configuration is not limited to this usage and may be used as an EDFA pumping light source of the oscillation wavelength of 980 nm and 1480 nm.

What is claimed is:

1. A semiconductor laser device for a pumping source comprising:
a light reflecting facet positioned on a first side of said semiconductor device;
a light emitting facet positioned on a second side of said semiconductor device thereby forming a resonator between said light reflecting facet and said light emitting facet;
an active layer configured to radiate light in the presence of an injection current, said active layer positioned within said resonator;
a wavelength selection structure positioned within said resonator and configured to select a spectrum of said light including multiple longitudinal modes, said spectrum being output from said light emitting facet; and
a modulation device configured to superimpose a modulation signal on said injection current in order to increase a spectrum width of each of said longitudinal modes.

2. The semiconductor laser device of claim 1, further comprising an attenuation device configured to attenuate an optical output power of said laser diode for reducing SBS.

3. The semiconductor laser device of claim 1, wherein said modulation device is configured to superimpose a sinusoidal modulation signal on said injection current.

4. The semiconductor laser device of claim 1, wherein said modulation device is configured to superimpose on the injection current a modulation signal having a modulation depth in the range of about 1%-10% of said injection current.

5. The semiconductor laser device of claim 2, wherein said modulation device is configured to superimpose on the injection current a modulation signal having a modulation depth in the range of about 0.1%-10% of said injection current.

6. The semiconductor laser device of claim 1, wherein said modulation device is configured to superimpose on the injection current a modulation signal having a modulation depth in the range of about 1%-10% of a light output of the laser device.

7. The semiconductor laser device of claim 2, wherein said modulation device is configured to superimpose on the injection current a modulation signal having a modulation depth in the range of about 0.1%-10% of said light output of the laser device.

8. The semiconductor laser device of claim 1, wherein said modulation device is configured to superimpose on the injection current a modulation signal having a modulation frequency of greater than 1 KHz.

9. The semiconductor laser device of claim 2, wherein said modulation device is configured to superimpose on the injection current a modulation signal having a modulation frequency of greater than 1 KHz.

10. The semiconductor laser device of claim 1, wherein said modulation device is configured to superimpose on the injection current a modulation signal having a modulation frequency approximately in the range of 1 KHz to 1 MHz.

11. The semiconductor laser device of claim 2, wherein said modulation device is configured to superimpose on the injection current a modulation signal having a modulation frequency approximately in the range of 1 KHz to 1 MHz.

12. The semiconductor laser device of claim 1, wherein said diffraction grating is positioned adjacent to said light emitting facet.

13. The semiconductor laser device of claim 2, wherein said diffraction grating is positioned adjacent to said light emitting facet.

14. The semiconductor device of claim 12, wherein a length of said partial diffraction grating and a length of said resonator are set to meet the inequality:
Lg×(1300/L)≦300,
where Lg is the predetermined length of the partial diffraction grating in μm, and
L is the length of the resonator in μm.

15. The semiconductor device of claim 12, wherein a length and a coupling coefficient of said partial diffraction grating are set to meet the inequality:
κ·Lg≦0.3,
where κ is the coupling coefficient of the diffraction grating, and
Lg is the length of the diffraction grating.

16. The semiconductor laser device of claim 1, wherein said diffraction grating is positioned adjacent to said light reflecting facet.

17. The semiconductor device of claim 16, wherein a length of said partial diffraction grating and a length of said resonator are set to meet the inequality:
Lg≦½L,
where Lg is the predetermined length of the partial diffraction grating in μm, and
L is the length of the resonator in μm.

18. The semiconductor device of claim 16, wherein a length and a coupling coefficient of said partial diffraction grating is set to meet the inequality:
κ·Lg≧1,
where κ is the coupling coefficient of the diffraction grating, and
Lg is the length of the diffraction grating.

19. The semiconductor laser device of claim 1, further comprising a current suppression region configured to suppress current injected into said wavelength selection structure.

20. The semiconductor laser device of claim 1, wherein said wavelength selection structure comprises a diffraction grating positioned along a portion of said active layer in a distributed feedback (DFB) configuration.

21. The semiconductor laser device of claim 20 wherein said diffraction grating comprises a chirped grating.

22. The semiconductor laser device of claim 1, wherein said wavelength selection structure comprises:
a wavepath layer positioned along a portion of the resonator length where no active layer exists in a distributed Bragg reflector (DBR) configuration; and
a diffraction grating positioned within the wavepath layer.

23. The semiconductor laser device of claim 22, wherein said diffraction grating comprises a chirped grating.

24. The semiconductor laser device of claim 22, further comprising:
a first electrode configured to provide said injection current and positioned along said active layer; and
a second electrode positioned along said wavepath layer and configured to supply a tuning current to the wavepath layer, wherein
said first electrode is electrically insulated from the second electrodes and said injection current and tuning current are independently adjustable, and
injection current is unmodulated and said modulation device is configured to superimpose a modulation signal on said tuning current.

25. The semiconductor laser device of claim 24, further comprising:
a phase adjustment layer positioned within said resonator along a portion of said resonator length interposed between said active layer and said wavepath layer; and
a third electrode positioned along said phase adjustment layer and electrically insulated from said first and second electrodes.

26. A semiconductor laser device comprising:
means for radiating light within the laser device;
means for oscillating said light within the laser device;
means for selecting a multiple longitudinal mode spectrum as a light output of said laser device; and
means widening a spectrum of each of said longitudinal modes.

27. A method of providing light having improved SBS characteristics from a semiconductor laser device for a pumping source comprising:
applying a drive current to the semiconductor laser device in order to output a light output having multiple longitudinal modes; and
modulating said drive current such that each longitudinal mode of the light output has an increased spectral width.

28. The method of claim 27, wherein said modulating comprises modulating the drive current with a signal having a modulation depth of 1%-10% of the drive current.

29. The method of claim 27, wherein said modulating comprises modulating the drive current with a signal having a modulation depth of 1%-10% of the light output.

30. The method of claim 27, wherein said modulating comprises modulating the drive current with a signal having a modulation frequency of more than 1 KHz.

31. The method of claim 27, wherein said modulating comprises modulating the drive current with a signal having a modulation frequency approximately in the range of 1 KHz to 1 MHz.

32. A semiconductor laser module for a pumping source comprising:
a semiconductor laser device comprising:
a light reflecting facet positioned on a first side of said semiconductor device,
a light emitting facet positioned on a second side of said semiconductor device thereby forming a resonator between said light reflecting facet and said light emitting facet,
an active layer configured to radiate light in the presence of an injection current, said active layer positioned within said resonator,
a wavelength selection structure positioned within said resonator and configured to select a spectrum of said light including multiple longitudinal modes, said spectrum being output from said light emitting facet, and
a modulation device configured to superimpose a modulation signal on said injection current in order widen a spectrum of each of said longitudinal modes; and
a wave guide device for guiding said laser beam away from the semiconductor laser device.

33. An optical fiber amplifier comprising:
a semiconductor laser device comprising:
a light reflecting facet positioned on a first side of said semiconductor device,
a light emitting facet positioned on a second side of said semiconductor device thereby forming a resonator between said light reflecting facet and said light emitting facet,
an active layer configured to radiate light in the presence of an injection current, said active layer positioned within said resonator,
a wavelength selection structure positioned within said resonator and configured to select a spectrum of said light including multiple longitudinal modes, said spectrum being output from said light emitting facet, and
a modulation device configured to superimpose a modulation signal on said injection current in order widen a spectrum of each of said longitudinal modes; and
an amplifying fiber coupled to said semiconductor laser device and configured to amplify a signal by using said light beam as an excitation light.

34. A wavelength division multiplexing system comprising:
a transmission device configured to provide a plurality of optical signals having different wavelengths;
an optical fiber amplifier coupled to said transmission device and including a semiconductor laser device comprising:
a light reflecting facet positioned on a first side of said semiconductor device,
a light emitting facet positioned on a second side of said semiconductor device thereby forming a resonator between said light reflecting facet and said light emitting facet,
an active layer configured to radiate light in the presence of an injection current, said active layer positioned within said resonator,
a wavelength selection structure positioned within said resonator and configured to select a spectrum of said light including multiple longitudinal modes, said spectrum being output from said light emitting facet, and
a modulation device configured to superimpose a modulation signal on said injection current in order widen a spectrum of each of said longitudinal modes; and
a receiving device coupled to said optical fiber amplifier and configured to receive said plurality of optical signals having different wavelengths.

35. A Raman amplifier comprising:
a semiconductor laser device comprising:
a light reflecting facet positioned on a first side of said semiconductor device,
a light emitting facet positioned on a second side of said semiconductor device thereby forming a resonator between said light reflecting facet and said light emitting facet,
an active layer configured to radiate light in the presence of an injection current, said active layer positioned within said resonator,
a wavelength selection structure positioned within said resonator and configured to select a spectrum of said light including multiple longitudinal modes, said spectrum being output from said light emitting facet, and
a modulation device configured to superimpose a modulation signal on said injection current in order widen a spectrum of each of said longitudinal modes; and
a fiber coupled to said semiconductor laser device and configured to carry a signal that is amplified based on said light beam being applied to said fiber.

36. The Raman amplifier of claim 35, wherein said semiconductor laser device is coupled to said fiber at an input side of said fiber such that said light beam is applied in a forward pumping method.

37. The Raman amplifier of claim 35, wherein said semiconductor laser device is coupled to said fiber at an output side of said fiber such that said light beam is applied in a backward pumping method.

38. The Raman amplifier of claim 35, wherein said semiconductor laser device is coupled to said fiber at both an input and output side of said fiber such that said light beam is applied in both a forward and backward pumping method.
